(19) United States
(12) Patent Application Publication
(10) Pub. No.: US 2005/0285624 A1
(43) Pub. Date: Dec. 29, 2005

(54) Hybrid pass gate level converting dual supply sequential circuit

(76) Inventors: Steven K. Hsu, Lake Oswego, OR (US); Amit Agarwal, West Lafayette, IN (US); Ram K. Krishnamurthy, Portland, OR (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/880,751

(22) Filed: Jun. 29, 2004

(51) Int. Cl. H03K 19/0175

(52) U.S. Cl. 326/80

(57) ABSTRACT

A device comprising a receiving circuit to receive an input signal, a voltage level converting circuit and a biasing circuit. The receiving circuit including an output and a first latch circuit coupled to a first supply node. The voltage level converting circuit includes a second latch circuit coupled to a second supply node, the second latch circuit including cross-coupled logic gates connected between first and second circuit nodes. The second supply node has a voltage level different from the first supply node. The biasing circuit has an input coupled to the receiving circuit output, and also has first and second outputs connectable to bias the first and second circuit nodes of the second latch circuit to complementary logic states based on the receiving circuit output.

### TECHNICAL FIELD

This document relates to voltage level converting circuits, and in particular to voltage level converting circuits.

### BACKGROUND

A desire for longer battery life has led designers of electronic devices and systems to pursue lower power designs. Integrated circuits such as microprocessors or memory devices are examples of such devices or systems. One approach in reducing the power consumed by such devices is to use multiple-supply voltage designs. This approach allows critical units of an integrated circuit to operate at a higher supply voltage while non-critical units operate at a lower supply voltage. Circuits that use a lower supply voltage consume less power and can have smaller device sizes, but such circuits tend to operate slower. Voltage level converters are used to translate electronic signals from circuits using a first supply voltage to circuits using a second supply voltage. What is needed are improved systems and methods to implement a multiple-supply design.

### BRIEF DESCRIPTION OF THE DRAWINGS

FIG. 1 shows a block diagram according to some embodiments of a level converting sequential circuit.

FIG. 2A is a circuit diagram according to some embodiments of a level converting sequential circuit.

FIG. 2B is a circuit diagram according to some embodiments of a level converting sequential circuit.

FIG. 3 is a timing diagram of the signals shown in the circuit diagram of FIG. 2A.

FIG. 4 is a block diagram according to some embodiments of a level converting sequential circuit.

FIG. 5 is a circuit diagram according to some embodiments of a level converting sequential circuit.

FIG. 6 is a block diagram according to some embodiments of an integrated circuit.

FIG. 7 is a block diagram according to some embodiments of a method for converting a voltage level.

### DETAILED DESCRIPTION

In the following detailed description, reference is made to the accompanying drawings which form a part hereof, and in which is shown by way of illustration specific embodiments in which the invention may be practiced. It is to be understood that other embodiments may be used and structural changes may be made without departing from the scope of the present invention.

This document describes voltage level converting sequential circuits. In multiple-supply electronic designs, one domain of an electronic device, system, or integrated circuit uses a first supply and another domain of an integrated circuit uses a second supply having a voltage level different than the first supply. The term “domain” refers to a section of an electronic device, system, or integrated circuit that is supplied with one supply voltage value. Domains are often grouped by area as well as supply value, but can be grouped by function as well. A voltage level converter circuit is used at an interface from one domain to another to convert low supply signals to high supply signals and vice versa. Level converter circuits often impose design trade-offs on designers. These trade-offs include having a multiple-supply design at the expense of longer signal delay, a larger amount of integrated circuit area consumed in the design and a larger amount of energy consumed by the design. It is desirable to reduce the penalties of signal delay, circuit area and energy drain imposed on designers of electronic devices and systems.

Sequential circuits such as flip-flop circuits are widely used in the design of electronic devices to temporarily store data and transfer the data from one part of a device to another. Embedding a voltage level converter into a flip-flop circuit reduces the penalties imposed on designers of multiple-supply systems. For example, area used by a design is reduced because the functionality of data storage and level converting are combined into a single circuit. Also, because a circuit consumes more energy during transitions from one logic level to another, a flip-flop design that reduces the transition times reduces the amount of energy used by the design as well as reducing the signal delays.

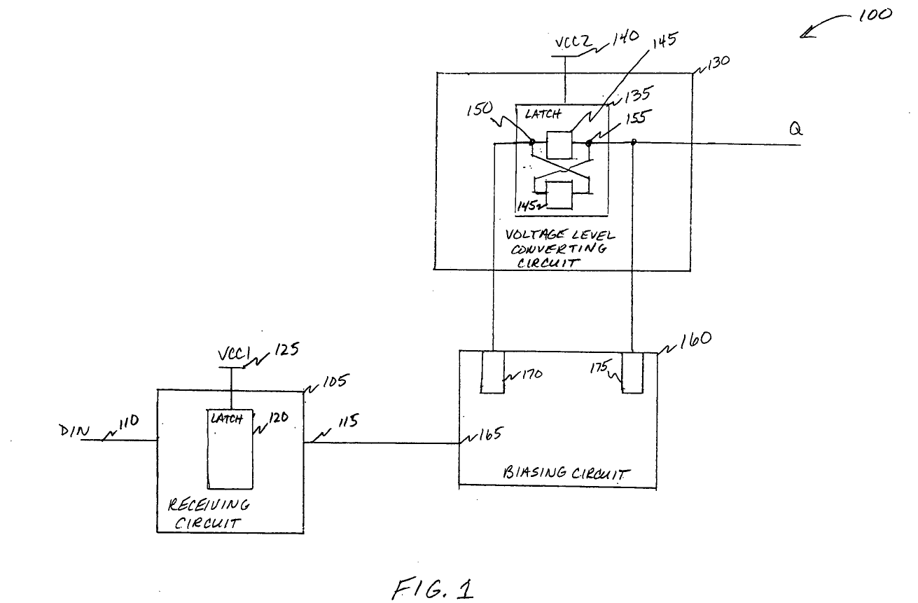

FIG. 1 shows a block diagram of an embodiment of a level converting sequential circuit 100. The circuit 100 includes a receiving circuit 105 to receive an input signal 110. The receiving circuit 105 includes an output 115 and a first latch circuit 120 coupled to a first supply node 125. The input signal 110 is capable of a voltage swing between a reference voltage, or potential, and a voltage level of the first supply node. The sequential circuit 100 also includes a voltage level converting circuit 130 that has a second latch circuit 135 coupled to a second supply node 140. The second latch circuit 135 includes cross-coupled logic gates 145 connected between first 150 and second 155 circuit nodes. The second supply node 140 has a voltage level different from the first supply node 125. In one embodiment, the second supply node 140 has a higher voltage level than the first supply node 125. In another embodiment, the second supply node 140 has a lower voltage level than the first supply node 125.

The sequential circuit further includes a biasing circuit 160 having an input 165 coupled to the receiving circuit output 115, and having first 170 and second 175 outputs connectable to bias the first 150 and second 155 circuit nodes of the second latch circuit 135 to complementary logic states based on the receiving circuit output 115. The voltage level converting circuit 130 is a cascade voltage switch logic (CVSL) circuit. Normally, CVSL circuits require devices to resolve contentions among internal circuit nodes. For example, a typical CVSL circuit would need pull-down N-fet transistors to pull only one of the first 150 or second 155 circuit nodes of the second latch in FIG. 1 to ground. Which node gets pulled to ground would depend on the input. The other circuit node is pulled high by the cross-coupled logic gates. Because the cross-coupled logic gates contend with one of the N-fets, to pull the one circuit node high the logic gates have to be sized larger, or upsized, to overcome the N-fet. According to the embodiments represented by FIG. 1, the biasing circuit 160 biases the first 150 and second 155 circuit nodes to logic states based on the receiving circuit output 115 thereby reducing the contention that normally occurs in CVSL circuits. This in turn reduces the transition time of the sequential circuit 100. Thus, using the biasing eliminates the need to upsize the logic gates.

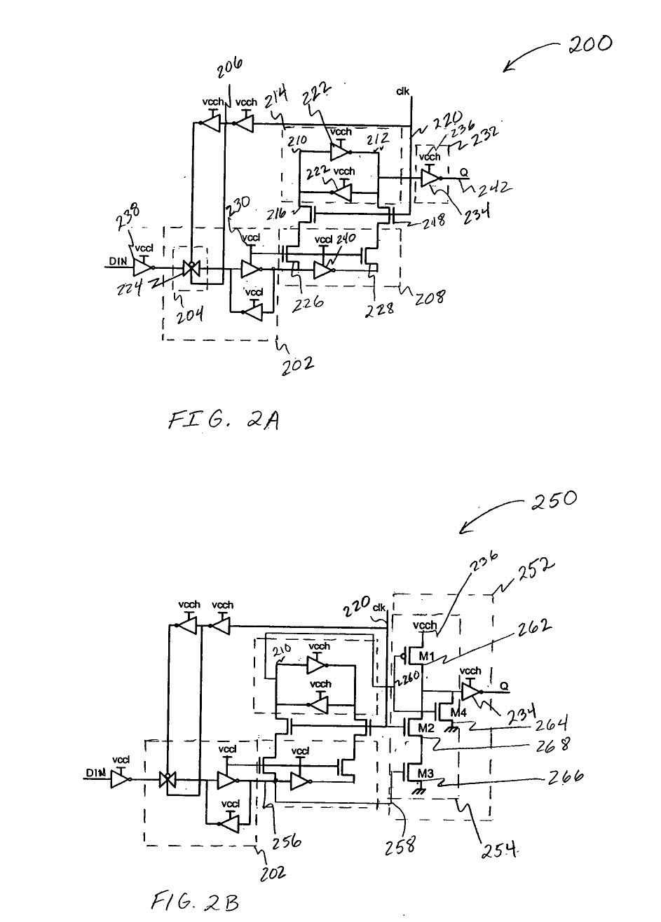

FIG. 2A is a circuit diagram according to some embodiments of a level converting sequential circuit 200. In some embodiments, the receiving circuit 202 includes an input circuit 204 clocked with a first clock signal 206, and the outputs of the biasing circuit 208 are connectable to the first and second circuit nodes 210, 212 of the voltage converting circuit 214 by a first switch 216 coupled to the first circuit node 210 and a second switch 218 coupled to the second circuit node 212. The biasing circuit 208 includes an inverter 240 to provide the logic states to the outputs. The first and second switches 216, 218 are controlled by a second clock signal 220. Thus the input signal is received on the first clock signal 206 and the input signal is converted during the second clock signal 220. In the embodiment shown, the first clock signal 206 is the second clock signal 220 inverted. In the embodiment shown, the cross-coupled logic gates 222 of the voltage converting circuit 214 include cross-coupled inverters. Some embodiments of the input circuit 204 include a pass gate 224. The pass gate is enabled using complementary versions of the first clock signal 206. The input of the pass gate 224 receives the input signal, and the output of the pass gate is coupled to an input of the first latch.

In some embodiments of the level converting sequential circuit 200, the outputs of the biasing circuit 208 include first and second transistors 226, 228 to prevent a short circuit from developing between the first 230 and second 236 supply nodes. The transistors 226, 228 have gate regions and source/drain regions. A first source/drain region of the first transistor 226 is coupled to the first switch 216 and a first source/drain region of the second transistor 228 is coupled to the second switch 218. The gate regions of the transistors 226, 228 are coupled to the first supply node 230. This biasing of the transistors 226, 228 restricts short circuit current from flowing between the two supply nodes 230, 236.

Some embodiments of the sequential circuit 200 include an output buffer circuit 232. In one example, the output buffer circuit 232 includes an inverting buffer 234 coupled to the second supply node 236. The input of the buffer 234 is coupled to the second circuit node 212 of the second latch of the voltage converter circuit 214. Because the buffer 234 is inverting, input buffer inverter 238 preserves the logic sense of the circuit output 242 (Q) and provides additional drive on the input signal. In another example, the input buffer 238 is non-inverting and the output buffer 234 is non-inverting. In another example, the output buffer 234 is non-inverting and the input is coupled to the first circuit node 210 of the second latch.

FIG. 2B is a circuit diagram of another embodiment of a level converting sequential circuit 250 useful to drive a high fanout load. The embodiment includes an output buffer circuit 252 that has a split-level output circuit 254 coupled to the receiving circuit output 256 and the first circuit node 210 of the second latch. A split-level output circuit 254 decouples the output drive stage from the level converting stage to further reduce signal delays caused by contention. The embodiment of a split-level output circuit 254 shown in the figure includes a first split-level input node 258 coupled to the receiving circuit output 256, a second split-level input node 260 coupled to the first circuit node 210 of the second latch, an inverter comprising transistors 262, 264 (M1, M4) having an input coupled to the second split-level input node 260 and a third transistor 266 (M3). The gate region of M3 is coupled to the first split-level input node 258, and a first source/drain region of M3 is coupled to a reference voltage level. The split-level output circuit 254 also includes a switch 268 (M2) coupled between a second source/drain region of transistor M3 and an output of the inverter. The switch 268 is controlled by the second clock signal 220.

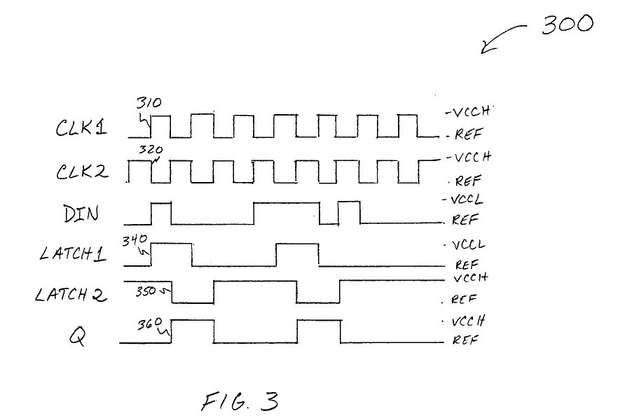

FIG. 3 is a timing diagram 300 of signals shown in the circuit diagram of FIG. 2A. The diagram 300 shows signals switching between voltage levels of the first or second supply nodes and the reference level. The relationship between the first and second clocks 310, 320 and the outputs of the first and second latches 340, 350 are shown. It can be seen from the diagram that the output of the sequential circuit Q 360 is level converted to the voltage level of the second supply node VCCH.

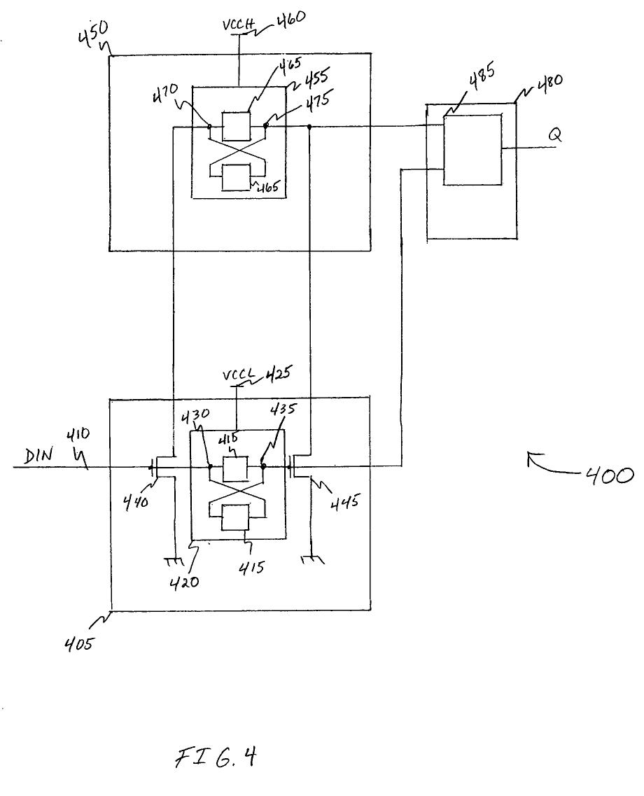

FIG. 4 is a block diagram of another embodiment of a level converting sequential circuit 400. In the embodiment, a receiving circuit 405 to receive an input signal 410 includes a first latch circuit 420 coupled to a first supply node 425. The first latch circuit 420 includes cross-coupled logic gates 415 connected between first 430 and second 435 circuit nodes. The first circuit node 430 receives the input signal 410. The receiving circuit 405 also includes a first pull-down transistor 440 and a second pull-down transistor 445. The gate region of the first pull-down transistor 440 is coupled to the first circuit node 430 of the first latch circuit 420, and the gate region of the second pull-down transistor 445 is coupled to the second circuit node 435 of the first latch circuit 420.

The level converting sequential circuit 400 also includes a voltage level converting circuit 450 that has a second latch circuit 455 coupled to a second supply node 460. The second supply node 460 has a voltage level different from the first voltage supply node 425. In one embodiment, the voltage level of the second supply node 460 is higher than a voltage level of the first supply node 425. The second latch circuit 455 includes cross-coupled logic gates 465 connected between first 470 and second 475 circuit nodes. The embodiment uses the two pull-down transistors 440, 445 instead of a biasing circuit. The pull-down transistors 440, 445 pull only one of the first 470 or second 475 circuit nodes of the second latch to the reference potential. Here the reference potential is ground. Which node gets pulled to ground depends on the input to the receiving circuit 405. The other circuit node is pulled high by the cross-coupled logic gates 465. The circuit nodes 470, 475 are connectable to the first 440 and second pull-down transistors 445. An output buffer circuit 480 of the sequential circuit 400 includes a split-level output circuit 485 coupled to circuit nodes of the first 420 and second 455 latches.

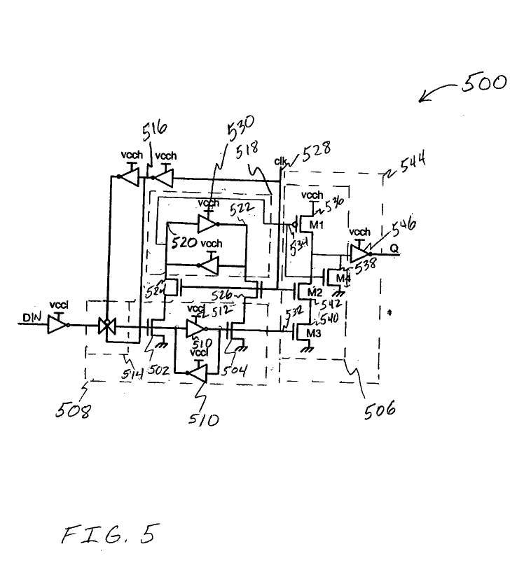

FIG. 5 is a diagram of another embodiment of a level converting sequential circuit 500 that includes pull-down transistors 502, 504 and a split-level output circuit 506. A latch in the receiving circuit 508 includes cross-coupled inverters 510. The receiving circuit 508 is coupled to a first supply node 512 and also includes an input circuit 514 clocked with a first clock signal 516. A voltage converting circuit 518 coupled to a second supply node 530 includes a second latch that has first and second circuit nodes 520, 522 connectable to the pull-down transistors 502, 504 by switches 524, 526. The switches are controlled by a second clock signal 528. In the embodiment shown, the first clock signal 516 is an inverted version of the second clock signal 528.

The split-level output circuit 506 includes a first split-level input node 532 coupled to a circuit node of the first latch, and a second split-level input node 534 coupled to a circuit node of the second latch. An inverter comprised of transistors 536, 538 (M1, M4) is coupled to the second split-level input node 534. A gate region of a transistor 540 (M3) is coupled to the first split-level input node 532, and a source/drain region is coupled to a reference voltage level. A switch 542 is coupled between the second source/drain region of the M3 transistor 540 and an output of the inverter. The switch 542 is controlled by the second clock signal 528. In another embodiment, the output circuit 544 further includes an output buffer circuit 546 coupled to the output of the inverter.

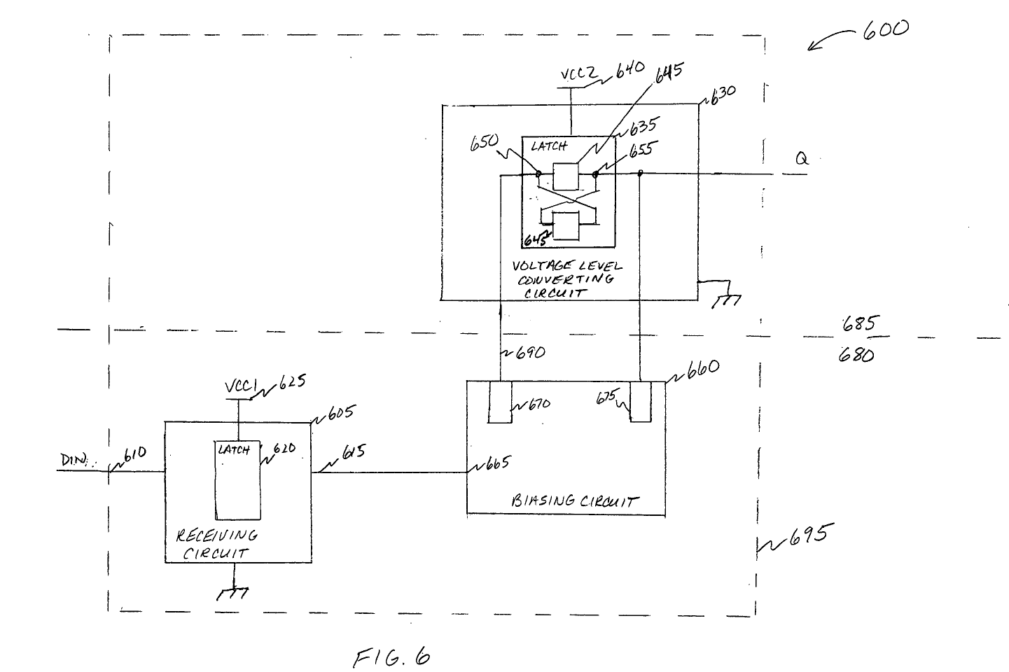

FIG. 6 shows a block diagram of a portion of an embodiment of an integrated circuit 600. The portion shown includes an interface between a first domain 680 and a second domain 685. The first domain 680 has a reference voltage node and a first supply node 625. The first domain 680 outputs at least a first data signal 690. The second domain 685 includes the reference voltage node and a second supply node 640. The second supply node has a voltage level different from the first supply node 625. In some embodiments, the voltage level of the second supply node 640 is higher than a voltage level of the first supply node 625.

The integrated circuit 600 includes at least one level converting sequential circuit 695 coupled to the first 680 and second 685 domains to pass the at least one data signal 690 from the first domain 680 to the second domain 685. The level converting sequential circuit 695 includes a receiving circuit 605 to receive an input signal 610, a voltage level converting circuit 630 and a biasing circuit 660. The receiving circuit 605 includes an output 615 and a first latch circuit 620 coupled to the first supply node 625. The voltage level converting circuit 630 includes a second latch circuit 635 coupled to the second supply node 640. The second latch circuit 635 includes cross-coupled logic gates 645 connected between first 650 and second 655 circuit nodes. The biasing circuit 660 has an input 665 coupled to the receiving circuit output 615, and also has first 670 and second 675 outputs connectable to bias the first 650 and second 655 circuit nodes of the second latch circuit 635 to complementary logic states based on the receiving circuit output 615.

In some embodiments of the integrated circuit 600, the level converting sequential circuit 695 further includes transistors coupled between the biasing circuit's outputs 670, 675 and circuit nodes 650, 655 of the second latch 635 to restrict short circuit current from flowing between the second supply node 640 and the first supply node 625. In other embodiments of the level converting sequential circuit 695, an output buffer circuit (not shown) is coupled to an output of the second latch circuit 635. In one such embodiment, the output buffer circuit includes a split-level output circuit (such as circuit 254 in FIG. 2B) coupled to outputs of the first 620 and second 635 latch.

Further embodiments represented by FIG. 6 include the integrated circuit 600 as any kind of integrated circuit. For example, integrated circuit 600 can be a processor such as a microprocessor. In another example, the integrated circuit 600 is an integrated circuit that is not a processor such as a memory (such as a dynamic random access memory), a memory controller, or a communications device.

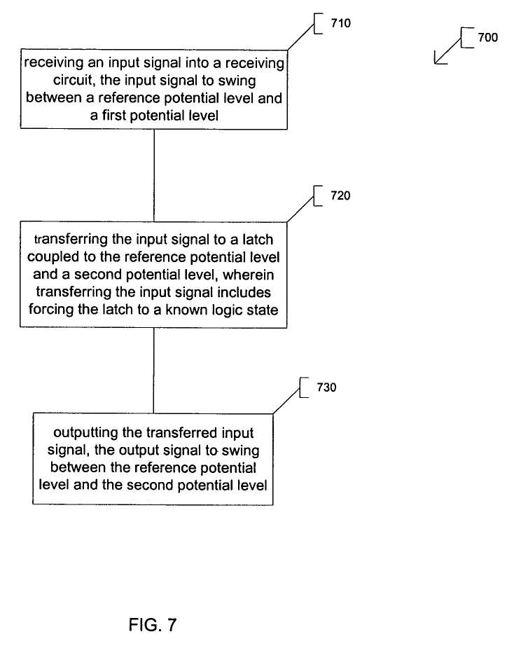

FIG. 7 is a block diagram of an embodiment of a method 700 for converting a voltage level. At 710, an input signal is received into a receiving circuit. The input signal has a voltage that swings between a reference potential level and a first potential level. At 720, the input signal is transferred to a latch coupled to the reference potential level and a second potential level. Transferring the input signal includes forcing the latch to a known logic state. The second potential level is different than the first potential level. For example, the second potential level may be higher than the first potential level.

In one version of the embodiment, forcing the latch to a known logic state includes forcing circuit nodes of cross-coupled logic gates of the latch to complementary logic states. In another version of the embodiment, the input to the receiving circuit is clocked into a receiving latch using a first clock signal and the latch coupled to the second potential level is forced using a second clock signal. In some embodiments, transferring the input signal includes restricting short circuit current from flowing between the second potential level and the first potential level. Restricting the short circuit currents includes placing devices between circuit nodes of the receiving latch and circuit nodes of the latch coupled to the second potential level. In some embodiments, the devices are transistors, such as transistors 226, 228 shown in FIG. 2A. In other embodiments, the devices are resistors.

At 730, the transferred input signal is output as an output signal having a voltage swing between the reference potential level and the second potential level. In one embodiment, outputting the input signal includes using an output circuit having a converting circuit stage decoupled from an output buffer stage. In one embodiment example, the decoupling is accomplished by including a split-level output circuit in an output buffer circuit.

The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

1. A device comprising:
a receiving circuit to receive an input signal, the receiving circuit including an output and a first latch circuit coupled to a first supply node;
a voltage level converting circuit including a second latch circuit coupled to a second supply node, the second latch circuit including cross-coupled logic gates connected between first and second circuit nodes, and wherein the second supply node has a voltage level different from the first supply node; and
a biasing circuit having an input coupled to the receiving circuit output, and having first and second outputs connectable to bias the first and second circuit nodes of the second latch circuit to complementary logic states based on the receiving circuit output.

2. The device of claim 1, wherein a voltage level of the second supply node is higher than a voltage level of the first supply node.

3. The device of claim 1, wherein the receiving circuit further includes an input circuit clocked with a first clock signal, and the biasing circuit outputs are connectable to the first and second circuit nodes by a first switch coupled to the first circuit node and a second switch coupled to the second circuit node, wherein the first and second switch are controlled by a second clock signal.

4. The device of claim 3, wherein the first and second bias circuit outputs include first and second transistors, the transistors having gate regions and source/drain regions, wherein a first source/drain region of the first transistor is coupled to the first switch and a first source/drain region of the second transistor is coupled to the second switch, and wherein the gate regions of the transistors are coupled to the first supply node.

5. The device of claim 3, wherein the input circuit includes a pass gate, the pass gate input receiving the input signal, the pass gate output coupled to an input of the first latch and the pass gate enabled using the first clock signal.

6. The device of claim 1 further including an output buffer circuit, wherein the output buffer circuit includes an inverter coupled to the second supply node, the input of the inverter coupled to a circuit node of the second latch.

7. The device of claim 1 further including an output buffer circuit, wherein the output buffer circuit includes a split-level output circuit coupled to the receiving circuit output and a circuit node of the second latch.

8. The device of claim 7, wherein the split-level output circuit includes:
a first split-level input node coupled to the receiving circuit output;
a second split-level input node coupled to a circuit node of the second latch;
an inverter, wherein the input of the inverter is coupled to the second split-level input node;
a transistor having a gate region and first and second source/drain regions, wherein the gate region is coupled to the first split-level input node, and the first source/drain region is coupled to a reference voltage level; and
a switch coupled between the second source/drain region of the transistor and an output of the inverter, the switch controlled by the second clock signal.

9. A device comprising:
a receiving circuit to receive an input signal, the receiving circuit including:
a first latch circuit coupled to a first supply node, the first latch circuit including cross-coupled logic gates connected between first and second circuit nodes, the first circuit node to receive the input signal;
a first pull-down transistor having a gate region coupled to the first circuit node of the first latch circuit; and
a second pull-down transistor having a gate region coupled to the second circuit node of the first latch circuit; and
a voltage level converting circuit including a second latch circuit coupled to a second supply node having a voltage level different from the first voltage supply node, the second latch circuit including cross-coupled logic gates connected between first and second circuit nodes, the first and second circuit nodes connectable to the first and second pull-down transistors; and
an output buffer circuit, the output buffer circuit including a split-level output circuit coupled to circuit nodes of the first and second latches.

10. The device of claim 9, wherein the voltage level of the second supply node is higher than a voltage level of the first supply node.

11. The device of claim 9, wherein the receiving circuit further includes an input circuit clocked with a first clock signal, and wherein the first and second circuit nodes of the second latch circuit are connectable to the first and second pull-down transistors by a first switch coupled between the first pull-down transistor and the first circuit node of the second latch, and a second switch coupled between the second pull-down transistor and the second circuit node of the second latch, wherein the first and second switch are controlled by a second clock signal.

12. The device of claim 9, wherein the split-level output circuit includes:
a first split-level input node coupled to a circuit node of the first latch;
a second split-level input node coupled to a circuit node of the second latch;
an inverter, wherein the input of the inverter is coupled to the second split-level input node;
a transistor having a gate region and first and second source/drain regions, wherein the gate region is coupled to the first split-level input node, and the first source/drain region is coupled to a reference voltage level; and
a switch coupled between the second source/drain region of the transistor and an output of the inverter, the switch controlled by the second clock signal.

13. The device of claim 12, wherein the output circuit further includes an output buffer circuit coupled to an output of the inverter.

14. An integrated circuit comprising:
a first domain having a reference voltage node and a first supply node, the first domain to output at least a first data signal;
a second domain having the reference voltage node and a second supply node, the second supply node having a voltage level different from the first supply node;
at least one interface circuit coupled to the first and second domains to pass the at least one data signal from the first domain to the second domain, the interface circuit including:
a receiving circuit to receive an input signal, the receiving circuit including an output and a first latch circuit coupled to the first supply node;
a voltage level converting circuit including a second latch circuit coupled to the second supply node, the second latch circuit including cross-coupled logic gates connected between first and second circuit nodes; and
a biasing circuit having an input coupled to the receiving circuit output, and having first and second outputs connectable to bias the first and second circuit nodes of the second latch circuit to complementary logic states based on the receiving circuit output.

15. The integrated circuit of claim 14, wherein the voltage level of the second supply node is higher than a voltage level of the first supply node.

16. The integrated circuit of claim 14, wherein the interface circuit further includes transistors coupled between the outputs of the biasing circuit and the circuit nodes of the second latch to restrict short circuit current from flowing between the second supply node and the first supply node.

17. The integrated circuit of claim 14, wherein the interface circuit further includes an output buffer circuit coupled to an output of the second latch.

18. The integrated circuit of claim 17, wherein the output buffer circuit includes a split-level output circuit coupled to outputs of the first and second latch.

19. The integrated circuit of claim 14, wherein the integrated circuit includes a microprocessor.

20. The integrated circuit of claim 14, wherein the integrated circuit is included in a memory.

21. A method comprising, receiving an input signal into a receiving circuit, the input signal to swing between a reference potential level and a first potential level;
transferring the input signal to a latch coupled to the reference potential level and a second potential level, wherein transferring the input signal includes forcing the latch to a known logic state; and
outputting the transferred input signal, the output signal to swing between the reference potential level and the second potential level.

22. The method of claim 21, wherein forcing the latch to a known logic state includes forcing cross-coupled logic gates connected between two circuit nodes to complementary logic states.

23. The method of claim 21, wherein transferring the input signal includes restricting short circuit current from flowing between the second potential level and the first potential level.

24. The method of claim 21, wherein receiving an input signal includes receiving the input signal using a first clock signal and wherein forcing the latch to a known logic state includes forcing the latch using a second clock signal.

25. The method of claim 21, wherein the second potential level is higher the first potential level.

26. The method of claim 21, wherein outputting the input signal includes using an output circuit having a converting circuit stage decoupled from an output buffer stage.

27. A system comprising, a microprocessor; and
a dynamic random access memory (DRAM), including:
a first domain having a reference voltage node and a first supply node, the first domain to output at least a first data signal;
a second domain having the reference voltage node and a second supply node, the second supply node having a voltage level different from the first supply node;
at least one interface circuit coupled to the first and second domains to pass the at least one data signal from the first domain to the second domain, the interface circuit including receiving circuit to receive an input signal, the receiving circuit including an output and a first latch circuit coupled to the first supply node;
a voltage level converting circuit including a second latch circuit coupled to the second supply node, the second latch circuit including cross-coupled logic gates connected between first and second circuit nodes; and
a biasing circuit having an input coupled to the receiving circuit output, and having first and second outputs connectable to bias the first and second circuit nodes of the second latch circuit to complementary logic states based on the receiving circuit output.

28. The system of claim 27, wherein the interface circuit further includes transistors coupled between the outputs of the biasing circuit and the circuit nodes of the second latch to restrict short circuit current from flowing between the second supply node and the first supply node.

29. The system of claim 27, wherein the interface circuit further includes an output buffer circuit, the output buffer circuit including a split-level output circuit coupled to outputs of the first and second latch.
